(19) United States
(12) Patent Application Publication
(10) Pub. No.: US 2026/0090253 A1
(43) Pub. Date: Mar. 26, 2026

(54) DISPLAY DEVICE

(71) Applicant: LG Display Co., Ltd., Seoul (KR)

(72) Inventors: Byunggwan HYUN, Paju-si (KR); Wonrae KIM, Paju-si (KR); Jiyoon CHOI, Paju-si (KR)

(73) Assignee: LG Display Co., Ltd., Seoul (KR)

(21) Appl. No.: 19/278,265

(22) Filed: Jul. 23, 2025

(30) Foreign Application Priority Data
Sep. 26, 2024 (KR) 10-2024-0130563

(51) Int. Cl. H10K 59/80; H10H 29/855; H10K 59/40; H10K 102/00

(52) U.S. Cl. CPC H10K 59/879; H10H 29/8552; H10K 59/40; H10K 59/8792; H10K 2102/351

(57) ABSTRACT

A display device according to one embodiment includes a substrate including a display area including a plurality of sub-pixels, and a non-display area surrounding the display area. A first electrode is disposed in each of the sub-pixels on the substrate, and a bank is disposed on the first electrode at boundaries between adjacent sub-pixels, overlapping the periphery of the first electrode's upper surface. An organic layer is on the first electrode and the bank, followed by a second electrode on the organic layer. A color filter is on the second electrode, and an optical member is on the color filter. The bank includes a black-based material to reduce external light reflection. The optical member includes a destructive interference layer and nano-patterns spaced apart from one another on the destructive interference layer to minimize reflectance and improve light management.

### CROSS REFERENCE TO RELATED APPLICATION

The present application claims priority to Korean Patent Application No. 10-2024-0130563, filed Sep. 26, 2024, the entire contents of which is expressly incorporated herein for all purposes by this reference.

### BACKGROUND

### Technical Field

The present specification relates to a device and particularly to, for example, without limitation, a display device.

### Description of the Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

The disclosed display device provides improved visual performance and energy efficiency by removing the polarizing film and incorporating a bank formed from a black-based material. This bank surrounds the light-emitting areas to absorb ambient light and reduce reflection, which enhances contrast and minimizes unwanted visual effects such as ring-shaped artifacts. Positioned above the color filter, an optical member with nano-scale patterns and a destructive interference layer alters the path of incoming light to significantly reduce surface reflectance and glare. This arrangement supports better visibility in bright environments and maintains luminance over a wider range of viewing angles by enabling broader light emission.

The structure also includes organic light-emitting layers with different thicknesses for each sub-pixel, which improves control of color output and display efficiency. Through this combination of structural light management, external light suppression, and tailored pixel design, the display achieves high contrast and low power consumption while maintaining mechanical flexibility. These features make it particularly suitable for mobile and wearable electronic devices.

For example, embodiments of the present specification are directed to providing a display device with improved flexibility by omitting a polarizing unit.

Embodiments of the present specification are also directed to providing a display device in which a color filter, and a bank including a black-based material are disposed to improve external light reflection.

Embodiments of the present specification are also directed to providing a display device in which an optical member is disposed on a color filter, thereby improving a reflectance of external light.

Embodiments of the present specification are also directed to providing a display device in which, since an optical member includes nano-patterns, it is possible to reduce or minimize a reflectance of external light and reduce a traveling angle of the external light.

Embodiments of the present specification are also directed to providing a display device in which, since an optical member includes a destructive interference layer under nano-patterns, it is possible to reduce or minimize a reflectance of external light.

Embodiments of the present specification are also directed to providing low-reflection display device in which surface reflection of external light is improved and which is driven with low power.

Technical benefits of the present specification are not limited to the above-described benefits, and other technical benefits may be inferred from the following embodiments.

According to one embodiment, there is provided a display device including a substrate including a display area including a plurality of sub-pixels, and a non-display area around the display area, a first electrode disposed in each of the sub-pixels on the substrate, a bank disposed on the first electrode and overlapping a periphery of an upper surface of the first electrode, an organic layer disposed on the first electrode and the bank, a second electrode on the organic layer, a color filter disposed on the second electrode, and an optical member on the color filter, wherein the bank includes a black-based material, and the optical member includes a destructive interference layer, and nano-patterns spaced apart from each other on the destructive interference layer.

According to another embodiment, there is provided a display device including a substrate including a display area including a plurality of sub-pixels, and a non-display area around the display area, a light-emitting part disposed in each of the sub-pixels on the substrate, an optical member including a destructive interference layer on the light-emitting part, and nano-patterns spaced apart from each other on the destructive interference layer, and an upper planarization layer disposed on the optical member and filling between the adjacent nano-patterns, wherein the nano-patterns change an optical path of external light, and the destructive interference layer destructively interferes with the external light of which the optical path has been changed.

Detailed matters of other embodiments are included in the detailed description and accompanying drawings.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of a display device according to one embodiment.

FIG. 2 is a cross-sectional view illustrating a bent state of a display panel according to FIG. 1 according to an embodiment of the present disclosure.

FIG. 3 is a cross-sectional view along line A-A′ in FIG. 1 according to an embodiment of the present disclosure.

FIG. 4 is a specific cross-sectional view of a light-emitting part of FIG. 3 according to an embodiment of the present disclosure.

FIG. 5 is a specific cross-sectional view of a light-emitting part according to a modified example according to an embodiment of the present disclosure.

FIG. 6 is a cross-sectional view of a touch part according to FIG. 3 according to an embodiment of the present disclosure.

FIG. 7 is a cross-sectional view along line B-B′ in FIG. 1 according to an embodiment of the present disclosure.

FIG. 8 is a cross-sectional view along line C-C′ in FIG. 1 according to an embodiment of the present disclosure.

FIG. 9 is an enlarged cross-sectional view of area Q1 in FIG. 3 according to an embodiment of the present disclosure.

FIG. 10 is an enlarged cross-sectional view of area Q2 in FIG. 9 according to an embodiment of the present disclosure.

FIG. 11 is an enlarged cross-sectional view of area Q3 in FIG. 9 according to an embodiment of the present disclosure.

FIG. 12 is a graph illustrating a reflectance according to a wavelength when nano-patterns are not disposed according to an embodiment of the present disclosure.

FIG. 13 is a graph illustrating a reflectance according to a wavelength when nano-patterns are disposed according to an embodiment of the present disclosure.

FIG. 14 is a plan view of nano-patterns according to one embodiment.

FIG. 15 is a cross-sectional view of a display device according to another embodiment.

FIG. 16 is a cross-sectional view of a display device according to still another embodiment.

FIG. 17 is a cross-sectional view of the display device according to still another embodiment.

FIG. 18 is a cross-sectional view of the display device according to still another embodiment.

FIG. 19 is a cross-sectional view of a display device according to yet another embodiment.

FIG. 20 is a perspective view of the display device according to yet another embodiment.

FIG. 21 is a cross-sectional view along line D-D′ in FIG. 20 according to yet another embodiment.

### DETAILED DESCRIPTION

Hereinafter, embodiments will be described with reference to the accompanying drawings.

In the following description, when a detailed description of well-known functions or configurations related to this document is determined to unnecessarily cloud a gist of the inventive concept, the detailed description thereof will be omitted or may be briefly discussed.

Advantages and features of the present disclosure, and implementation methods thereof will be clarified through the following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure.

Throughout the drawings and the detailed description, unless otherwise described, the same drawing reference numerals should be understood to refer to the same elements, features, and structures.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Any implementation described herein as an “example” is not necessarily to be construed as preferred or advantageous over other implementations.

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

In the specification, when a first component (or an area, a layer, a portion, etc.) is described as “on,” “connected,” or “coupled to” a second component, it means that the first component may be directly connected/coupled to the second component or a third component may be disposed therebetween.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc., can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance. Features of various embodiments of the present specification may be coupled or combined partially or entirely, various technological interworking and driving are made possible, and the embodiments may be implemented independently of each other or implemented together in an associated relationship.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

It will be apparent to those skilled in the art that various modifications and variations can be made in the vibration apparatus and the sound apparatus including the same of the present disclosure without departing from the technical idea or scope of the disclosures. Thus, it is intended that the present disclosure covers the modifications and variations of this disclosure provided they come within the scope of the appended claims and their equivalents.

Hereinafter, a display device of the present specification will be described with reference to the accompanying drawings and embodiments as follows.

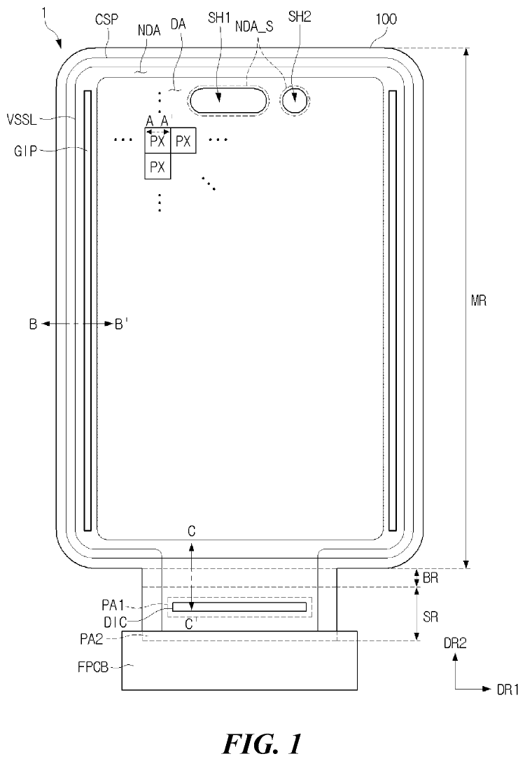

FIG. 1 is a plan view of a display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, the embodiments of the present specification are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as or similar to an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH surrounded by the sensor non-display area NDA_S. The sensor hole SH1 and SH2 may be surrounded by the display area DA in a plan view. The number of sensor holes SH1 and SH2 may be, for example, two as in FIG. 1, but the embodiments of the present specification are not limited thereto. For example, the sensor hole may be provided as one sensor hole. The two sensor holes SH1 and SH2 may each include a sensor hole in which an infrared sensor is disposed and a sensor hole in which a camera sensor is disposed, but the embodiments of the present specification are not limited thereto. A sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S.

A gate driving unit GIP may be disposed in the non-display area NDA located at one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be located outside the gate driving unit GIP on the non-display area NDA, and disposed to surround the display area DA.

The non-display area NDA located at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

A display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. The display device 1 may further include a data driving unit DIC and a printed circuit board FPCB. The data driving unit DIC may be disposed in a first pad area PA1, and the printed circuit board FPCB may be attached to a second pad area PA2. A plurality of pads connected to the data driving unit DIC and the printed circuit board FPCB may be disposed in each of the first pad area PA1 and the second pad area PA2. The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the present specification are not limited thereto, and the data driving unit DIC may be disposed by a chip on glass or chip on film method.

The display panel 100 according to one embodiment may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, the embodiments of the present specification are not limited thereto, and a part of the crack sensing pattern CSP may not be disposed in the non-display area NDA of the other side of the display area DA in the second direction DR2.

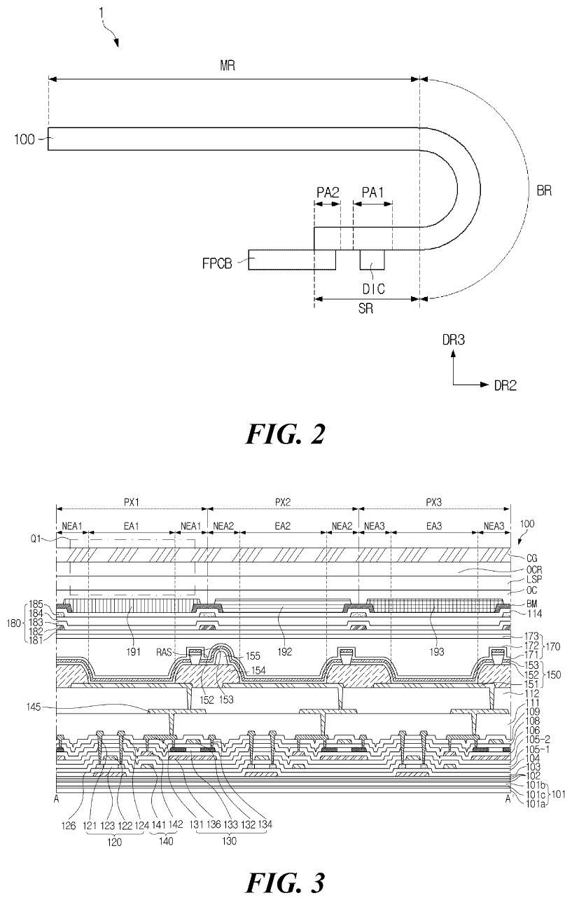

FIG. 2 is a cross-sectional view illustrating a bent state of a display panel according to FIG. 1.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

FIG. 3 is a cross-sectional view along line A-A′ in FIG. 1.

Referring to FIG. 3, the pixel PX (see FIG. 1) of the display panel 100 may include a plurality of sub-pixels PX1, PX2, and PX3. A first sub-pixel PX1 may be a red sub-pixel, a second sub-pixel PX2 may be a green sub-pixel, and a third sub pixel PX3 may be a blue sub-pixel, but the embodiments of the present specification are not limited thereto. In some embodiments, the pixel PX further includes a fourth sub-pixel, and the fourth sub-pixel may be a white sub-pixel, but the embodiments of the present specification are not limited thereto. In some embodiments, the pixel may include one red sub-pixel, two green sub-pixels, and one blue sub-pixel, but the embodiments of the present specification are not limited thereto. For example, the plurality of sub-pixels PX1, PX2, and PX3 may be arranged in a stripe manner in the first direction DR1, but are not limited thereto, and may be arranged in a pentile manner.

The display panel 100 may include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present specification are not limited thereto.

The buffer layer 102 may be disposed on the substrate 101. The buffer layer 102 can reduce or minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

A first light-shielding layer 126 may be disposed on the buffer layer 102. The first light-shielding layer 126 can reduce or prevent light from transmitting a first semiconductor layer 123 of the first thin film transistor 120. For example, the first semiconductor layer 123 may be disposed to overlap the first light-shielding layer 126. The first light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

The first insulating layer 103 may be disposed on the buffer layer 102 and the first light-shielding layer 126. The first insulating layer 103 can reduce or prevent a short circuit between a component of the first thin film transistor 120 and the first light-shielding layer 126. The first insulating layer 103 may be formed of the same material as the buffer layer 102, but the embodiments of the present specification are not limited thereto. For example, the first insulating layer 103 may be formed of an inorganic insulation material, such as silicon nitride (SiNₓ) or silicon oxide (SiOₓ), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

The second insulating layer 104 may be disposed on the first semiconductor layer 123. The second insulating layer 104 may be formed of the same material as the first insulating layer 103 and can reduce or prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto. The first gate electrode 122 may be disposed along with a gate line.

The third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present specification are not limited thereto. For example, the 3-1 insulating layer 105-1 may include silicon oxide (SiOₓ), and the 3-2 insulating layer 105-2 may include silicon nitride (SiNₓ), but the embodiments of the present specification are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the present specification are not limited thereto.

A storage electrode 140 may be disposed to be spaced apart from the first thin film transistor 120. The storage electrode 140 may include a first storage electrode 141 and a second storage electrode 142.

The first storage electrode 141 may be formed of the same material as the first gate electrode 122 and disposed on the same layer as the first gate electrode 122, but the embodiments of the present specification are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can reduce or prevent light from traveling to the second semiconductor layer 133 similar to the first light-shielding layer 126, thereby extending the life of the second thin film transistor 130. For example, the second semiconductor layer 133 may be disposed to overlap the second light-shielding layer 136.

The fourth insulating layer 106 may be disposed on the second light-shielding layer 136. The fourth insulating layer 106 may be formed of the same material as the first insulating layer 103, the second insulating layer 104, or the third insulating layers 105-1 and 105-2, but the embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

The fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present specification are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto.

The sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present specification are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present specification are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present specification are not limited thereto.

The first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present specification are not limited thereto.

The second protective layer 112 may be disposed on the first protective layer 111. The second protective layer 112 may be formed of the same material as the first protective layer 111, but the embodiments of the present specification are not limited thereto.

In some embodiments, a third protective layer may be further disposed on an upper surface of the second protective layer 112, but the embodiments of the present specification are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present specification are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The light-emitting part 150 may be disposed on the second protective layer 112. The light-emitting part 150 may include a first electrode 151, an organic layer 152, and a second electrode 153. The first electrode 151 may serve as an anode, and the second electrode 153 may serve as a cathode.

The first electrode 151 may be disposed on the second protective layer 112. The first electrode 151 may be electrically connected to the first thin film transistor 120 through a contact hole formed in the second protective layer 112. The first electrode 151 may be a reflective electrode that reflects light, but the embodiments of the present specification are not limited thereto. The first electrode 151 may include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto. For example, the organic layer 152 of the display panel 100 according to one embodiment of the present specification may include an organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto. Hereinafter, a specific structure of the organic layer 152 according to one embodiment will be described.

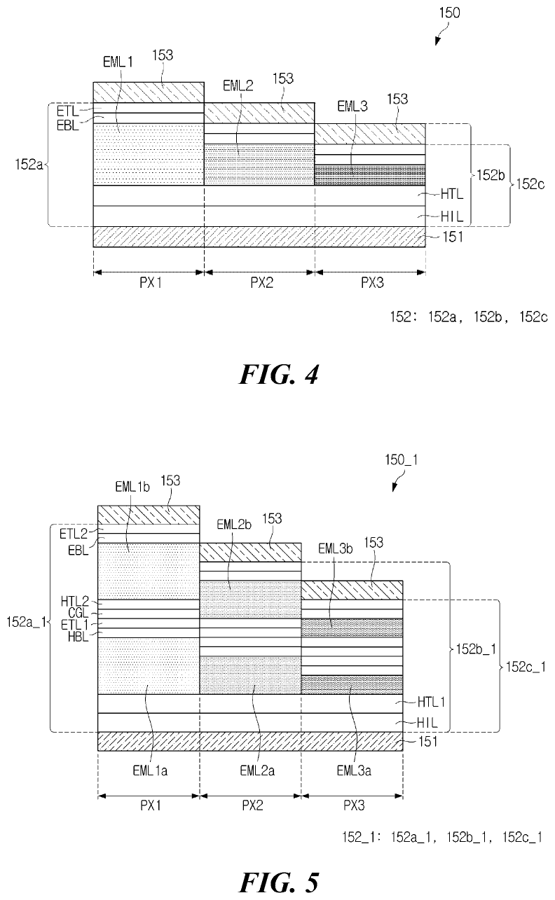

FIG. 4 is a specific cross-sectional view of a light-emitting part of FIG. 3.

Referring to FIG. 4, the light-emitting part 150 may include the first sub-pixel PX1, the second sub-pixel PX2, and the third sub-pixel PX3.

A thickness of the light-emitting part 150 in each sub-pixel PX1, PX2, or PX3 may be different, but the embodiments of the present specification are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present specification are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels PX1, PX2, and PX3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidinc), PPD, TTBND, FFD, p-dmDPS, and TAPC, starburst aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyIN,N′-diphenyl benzidine), s-TAD, and MTDATA (4,4′,4″-Tris(N-3-methylphenyl-N-phenyl-amino)-triphenylamine), but the embodiments of the present specification are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

A thicknesses of each light-emitting layer EML1, EML2, or EML3 may be different. For example, the first light-emitting layer EML1 may be formed in a thickness of 600 to 800 Å, the second light-emitting layer EML2 may be formed in a thickness of 300 to 500 Å, and the third light-emitting layer EML3 may be formed in a thickness of 100 to 300 Å, but the embodiments of the present specification are not limited thereto.

Each of the first light-emitting layer EML1, the second light-emitting layer EML2, and the third light-emitting layer EML3 may include a material that may emit light in the visible light range by receiving and combining holes and electrons.

An electron blocking layer EBL may be disposed on each light-emitting layer EML1, EML2, or EML3. The electron blocking layer EBL may be disposed integrally across the sub-pixels PX1, PX2, and PX3.

An electron transporting layer ETL may be disposed on the electron blocking layer EBL. The electron transporting layer ETL may be disposed integrally across the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the electron transporting layer ETL.

FIG. 5 is a specific cross-sectional view of a light-emitting part according to a modified example.

Referring to FIGS. 4 and 5, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 may be physically separated, but the lower layers and upper layers of the light-emitting layers may be formed integrally across the sub-pixels PX1, PX2, and PX3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present specification are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be formed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present specification are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels PX1, PX2, and PX3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidinc), PPD, TTBND, FFD, p-dmDPS, and TAPC, starburst aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthyIN,N′-diphenyl benzidine), s-TAD, and MTDATA (4,4′,4″-Tris(N-3-methylphenyl-N-phenyl-amino)-triphenylamine), but the embodiments of the present specification are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2a may be disposed in the second sub-pixel PX2, and a 3-1 light-emitting layer EML3a may be disposed in the third sub-pixel PX3. Each of the light-emitting layers EML1a, EML2a, and EML3a may be the same as or similar to each of the light-emitting layers EML1, EML2, and EML3 of FIG. 4.

A thicknesses of each light-emitting layer EML1a, EML2a, or EML3a may be different. For example, the 1-1 light-emitting layer EML1a may be formed in a thickness of 600 to 800 Å, the 2-1 light-emitting layer EML2a may be formed in a thickness of 300 to 500 Å, and the 3-1 light-emitting layer EML3a may be formed in a thickness of 100 to 300 Å, but the embodiments of the present specification are not limited thereto.

A hole blocking layer HBL may be disposed on each light-emitting layer EML1a, EML2a, or EML3a. The hole blocking layer HBL may be disposed integrally across the sub-pixels PX1, PX2, and PX3.

A first hole transporting layer HTL1 may be disposed on the hole blocking layer HBL. The first electron transporting layer ETL1 may be formed integrally across the sub-pixels PX1, PX2, and PX3. The first electron transporting layer ETL1 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

A common charge layer CGL may be disposed on the first electron transporting layer ETL1. The common charge layer CGL may be disposed between the first electron transporting layer ETL1 and the second hole transporting layer HTL2. The common charge layer CGL may include a conductive material, but the embodiments of the present disclosure are not limited thereto.

A second hole transporting layer HTL2 may be disposed on the common charge layer CGL. The second hole transporting layer HTL2 may be disposed between the hole blocking layer HBL and the light-emitting layers EML1b, EML2b, and EBL3b. The second hole transporting layer HTL2 may be formed integrally across the sub-pixels PX1, PX2, and PX3. A material of the second hole transporting layer HTL2 may be the same as or similar to a material of the first hole transporting layer HTL1, but the embodiments of the present specification are not limited thereto.

The light-emitting layers EMLIb, EML2b, and EML3b may be disposed on the second hole transporting layer HTL2. A 1-2 light-emitting layer EML1b may be disposed in the first sub-pixel PX1, a 2-2 light-emitting layer EML2b may be disposed in the second sub-pixel PX2, and a 3-2 light-emitting layer EML3b may be disposed in the third sub-pixel PX3. Each of the light-emitting layers EML1b, EML2b, and EML3b may be the same as or similar to each of the light-emitting layers EML1a, EML2a, and EML3a.

A thicknesses of each light-emitting layer EML1b, EML2b, or EML3b may be different. For example, the 1-2 light-emitting layer EML1b may be formed in a thickness of 600 to 800 Å, the 2-2 light-emitting layer EML2b may be formed in a thickness of 300 to 500 Å, and the 3-2 light-emitting layer EML3b may be formed in a thickness of 100 to 300 Å, but the embodiments of the present specification are not limited thereto.

An electron blocking layer EBL may be disposed on each light-emitting layer EML1b, EML2b, or EML3b. The electron blocking layer EBL may be disposed integrally across the sub-pixels PX1, PX2, and PX3.

A second electron transporting layer ETL2 may be disposed on the electron blocking layer EBL. The second electron transporting layer ETL2 may be formed integrally across the sub-pixels PX1, PX2, and PX3. The second electron transporting layer ETL2 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present specification are not limited thereto.

The second electrode 153 may be disposed on the second electron transporting layer ETL2.

Referring back to FIG. 3, the second electrode 153 may be disposed on the organic layer 152. The second electrode 153 may be a transparent electrode that transmits light, but the embodiments of the present specification are not limited thereto. For example, the second electrode 153 may include a transparent conductive material, such as indium tin oxide (ITO) or indium zinc oxide (IZO), or a metal that transmits visible light, but the embodiments of the present specification are not limited thereto.

The bank 154 may be disposed to expose the first electrode 151. The bank 154 may define openings (or the light-emitting areas EA1, EA2, and EA3) of the sub-pixels PX1, PX2, and PX3 and may be disposed to cover an edge portion (or a periphery) of the first electrode 151. That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may include a black-based material. For example, the bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be a black bank. When the bank 154 is formed of a material containing black pigment or black dye, it is possible to shield external light or light reflected from the outside, thereby further increasing the luminance of the display device.

A barrier RAS may be further disposed on the bank 154. As illustrated in FIG. 3, the barrier RAS may be disposed at all the boundaries NEA1, NEA2, and NEA3 between the sub-pixels PX1, PX2, and PX3, but the embodiments of the present specification are not limited thereto. The barrier RAS may be disposed directly on an upper surface of the bank 154, but the embodiments of the present specification are not limited thereto. The barrier RAS may serve to separate the organic layer 152 from the boundaries of adjacent sub-pixels PX1, PX2, and PX3. In some embodiments, the barrier may be omitted or may be briefly provided, and a trench may be formed in the bank 154. The trench may recess the bank 154 in the thickness direction.

A spacer 155 may be further disposed on the bank 154. The spacer 155 may be formed of the same material as the bank 154, but the embodiments of the present specification are not limited thereto. For example, the spacer 155 may be a transparent bank, but is not limited thereto, and the spacer 155 may be formed of the same material as the bank 154. For example, the spacer 155 may be disposed on at least one of the boundaries of the first to third sub-pixels PX1, PX2, and PX3, but the embodiments of the present specification are not limited thereto. The bank 154 and the spacer 155 may be formed of the same material and formed simultaneously through a halftone mask, but the embodiments of the present specification are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present specification are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present specification are not limited thereto.

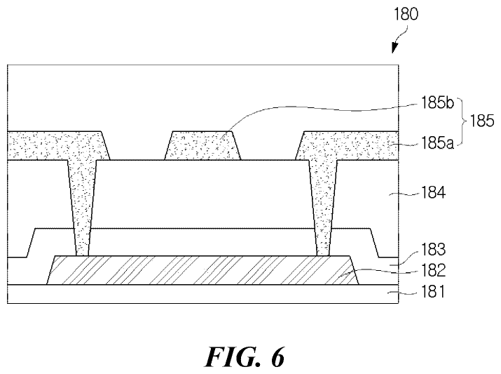

FIG. 6 is a cross-sectional view of a touch part according to FIG. 3.

Referring to FIGS. 3 and 6, the touch buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present specification are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be reduced or prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can reduce or prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present specification are not limited thereto. The second touch insulating layer 184 may include an organic insulation material, but the embodiments of the present specification are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

Referring back to FIG. 3, the filter insulating layer 114 may be disposed on the second touch conductive layer. The filter insulating layer 114 may be formed of an inorganic insulation material, such as silicon nitride (SiNₓ) or silicon oxide (SiOₓ), but the embodiments of the present specification are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be reduced or prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the present specification are not limited thereto. In the case of the display panel 100 according to one embodiment, since the bank 154 may include a black-based material and the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3 and the bank 154 is formed of only a transparent material, light incident from the outside may be reflected by the bank 154, resulting in visible ring-shaped spots. However, in the case of the display panel 100 according to one embodiment, the light incident from the outside may be absorbed or blocked by the bank 154 including a black-based material, thereby reducing or preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. The first color filter 191 may be provided to block light of other colors not including red (R) light. In this case, the first color filter 191 may be provided as a red color filter. The second color filter 192 may be provided to block light of other colors not including green (G) light. In this case, the second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present specification are not limited thereto.

For example, each color filter 191, 192, or 193 may come into direct contact with side and upper surfaces of the black matrix BM. For example, each color filter 191, 192, or 193 may be spaced apart from the boundaries of adjacent sub-pixels PX1, PX2, and PX3, but the embodiments of the present specification are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material.

An optical member LSP may be disposed on the planarization layer OC. The optical member LSP may serve to improve a reflectance of external light incident from the top of the display panel 100. The optical member LSP will be described in detail below.

An upper planarization layer OCR may be disposed on the optical member LSP. For example, the upper planarization layer OCR may include an organic insulation material.

A cover layer CG may be disposed on the upper planarization layer OCR. The cover layer CG may be formed of a glass material including glass, quartz, etc., but the embodiments of the present specification are not limited thereto, and the cover layer CG may be formed of a plastic material. The cover layer CG may be disposed above the display panel 100 to protect members disposed under the cover layer CG from the outside. The cover layer CG may be a cover layer formed by chemical reinforcement, but the embodiments of the present specification are not limited thereto. The cover layer CG may be a cover window, a window cover, or a cover member, but the embodiments of the present specification are not limited thereto.

An anti-reflective layer capable of reducing the reflectance of external light may be additionally disposed on the cover layer CG, but the embodiments of the present specification are not limited thereto.

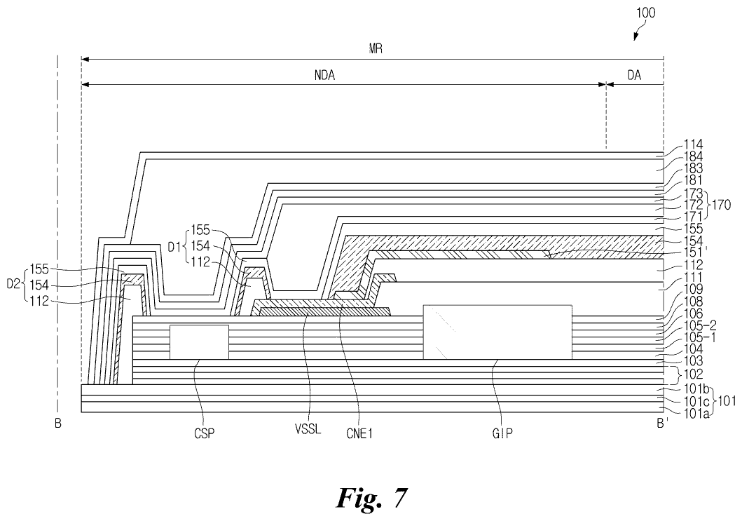

FIG. 7 is a cross-sectional view along line B-B′ in FIG. 1.

Referring to FIG. 7, at least one of the panel inorganic layers 102, 103, 104, 105-1, 105-2, 106, 108, and 109 may not extend to an end portion of the substrate 101. That is, the at least one of the panel inorganic layers 102, 103, 104, 105-1, 105-2, 106, 108, and 109 may expose the end portion of the substrate 101, but the embodiments of the present specification are not limited thereto.

The display panel 100 according to one embodiment may further include the crack sensing pattern CSP, the low-potential voltage line VSSL, and the gate driving unit GIP. As described above in FIG. 1, the low-potential voltage line VSSL may be located between the crack sensing pattern CSP and the display area DA, and the gate driving unit GIP may be located between the low-potential voltage line VSSL and the display area DA.

For example, as illustrated in FIG. 7, the gate driving unit GIP may be formed of a conductive layer located on the same layer as the first gate electrode 122 (see FIG. 3), a conductive layer located on the same layer as the second light-shielding layer 136 (see FIG. 3), or a conductive layer located on the same layer as the first source electrode 121, but the embodiments of the present specification are not limited thereto.

For example, the crack sensing pattern CSP may be disposed between a first dam D1 and a second dam D2. The crack sensing pattern CSP may be formed of a conductive layer located on the same layer as the first gate electrode 122 (see FIG. 3) or a conductive layer located on the same layer as the second light-shielding layer 136 (see FIG. 3), but the embodiments of the present specification are not limited thereto. For example, the crack sensing pattern CSP may include a conductive layer located on the same layer as the first source electrode 121, but the embodiments of the present specification are not limited thereto.

The low-potential voltage line VSSL may be disposed between the crack sensing pattern CSP and the gate driving unit GIP. The low-potential voltage line VSSL may be formed of a conductive layer located on the same layer as the first source electrode 121, but the embodiments of the present specification are not limited thereto.

The first protective layer 111 may cover the gate driving unit GIP, partially cover one end portion of the low-potential voltage line VSSL, and expose the other end portion of the low-potential voltage line VSSL. In the present specification, the one end portion may refer to an area of a certain component, which is located in a direction from the non-display area NDA toward the display area DA, and the other end portion may refer to an area of the certain component, which is located in a direction from the display area DA toward the non-display area NDA.

A first connection electrode CNE1 located on the same layer as the connection electrode 145 may be disposed on the first protective layer 111. The first connection electrode CNE1 may be directly connected to an area of the low-potential voltage line VSSL, in which the first protective layer 111 is exposed. The first connection electrode CNE1 may cover the other end portion of the low-potential voltage line VSSL, but the embodiments of the present specification are not limited thereto.

The second protective layer 112 may be disposed on the first connection electrode CNE1. The second protective layer 112 may come into direct contact with and cover one end portion of the first connection electrode CNE1 and expose the other end portion of the first connecting electrode CNE1. The second protective layer 112 may form a first layer of the first dam D1 and a first layer of the second dam D2. The second dam D2 may overlap, for example, the low-potential voltage line VSSL and cover the other end portion of the low-potential voltage line VSSL. The second dam D2 may come into direct contact with the first connection electrode CNE1 and cover the other end portion of the first connection electrode CNE1. The second protective layer 112 forming the first layer of the first dam D1 may come into direct contact with the exposed side surfaces of at least one of the panel inorganic layers 102, 103, 104, 105, 106, 107, and 109 and may come into direct contact with the upper surface of the substrate 101, but the embodiments of the present specification are not limited thereto. The second protective layer 112 may overlap the gate driving unit GIP. In the present specification, the dam is, for example, provided as two dams, but the dam may be provided as three or more dams or one dam.

A low-potential connection electrode 151′ located on the same layer as the first electrode 151 (see FIG. 3) may be disposed on the first connection electrode CNE1 exposed by the second protective layer 112 and the second protective layer 112. The low-potential connection electrode 151′ may be electrically connected to the first connection electrode CNE1 exposed by the second protective layer 112. The low-potential connection electrode 151′ may be electrically connected to the second electrode 153 (see FIG. 3) described above in FIG. 3.

The bank 154 may be disposed on the low-potential connection electrode 151′ and the second protective layer 112. The bank 154 may overlap the gate driving unit GIP, overlap the low-potential connection electrode 151′, and cover the other end portion of the low-potential connection electrode 151′. The bank 154 may completely cover the low-potential connection electrode 151′, but the embodiments of the present specification are not limited thereto. The bank 154 may expose a central portion and the other end portion of the first connection electrode CNE1, but the embodiments of the present specification are not limited thereto. The bank 154 may form a second layer of the first dam D1 and a second layer of the second dam D2. In each dam D1 or D2, the bank 154 may overlap the second protective layer 112 forming the first layer and completely cover the second protective layer 112, but the embodiments of the present specification are not limited thereto. In the second dam D2, the bank 154 may come into contact with the side surfaces of the second protective layer 112 and the upper surface of the substrate 101, but the embodiments of the present specification are not limited thereto.

The spacer 155 may be disposed on the bank 154. The spacer 155 may overlap the gate driving unit GIP. The spacer 155 may form a third layer of the dams D1 and D2. The spacer 155 forming the third layer of each dam D1 or D2 may overlap the bank 154 forming the second layer and completely cover the bank 154, but the embodiments of the present specification are not limited thereto. In the second dam D2, the spacer 155 may come into contact with the side surfaces of the bank 154 and the upper surface of the substrate 101, but the embodiments of the present specification are not limited thereto.

The encapsulation part 170 may be disposed on the spacer 155. The first encapsulation layer 171 may extend to the gate driving unit GIP, the low-potential voltage line VSSL, the first dam D1, and the second dam D2 and cover an outer surface of the second dam D2. The second encapsulation layer 172 may end at the first dam D1. The second encapsulation layer 172 may overlap the gate driving unit GIP and the low-potential voltage line VSSL. The third encapsulation layer 173 may extend to the gate driving unit GIP, the low-potential voltage line VSSL, the first dam D1, and the second dam D2 and come into direct contact with the first encapsulation layer 171 on the first dam D1, the crack sensing pattern CSP, and the second dam D2.

The touch buffer layer 181 and the first touch insulating layer 183 may extend to the gate driving unit GIP, the low-potential voltage line VSSL, the first dam D1, and the second dam D2 and cover the outer surface of the second dam D2. The second touch insulating layer 184 may extend to the gate driving unit GIP, the low-potential voltage line VSSL, the first dam D1, and the crack sensing pattern CSP and end on the second dam D2, but the embodiments of the present specification are not limited thereto.

The filter insulating layer 114 may extend to the gate driving unit GIP, the low-potential voltage line VSSL, the first dam D1, and the second dam D2 and come into direct contact with an outer surface of the second touch insulating layer 184, but the embodiments of the present specification are not limited thereto.

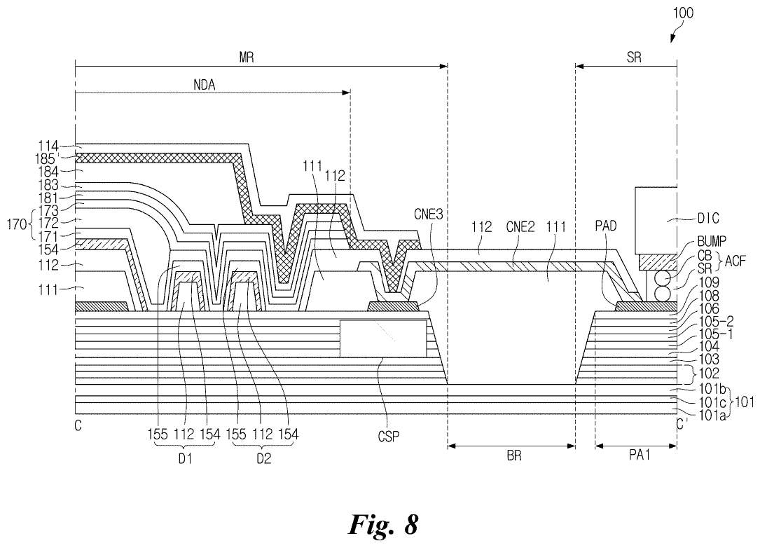

FIG. 8 is a cross-sectional view along line C-C′ in FIG. 1.

Referring to FIGS. 3, 7, and 8, the bending region BR may be disposed between the sub-region SR and the crack sensing pattern CSP. In the bending region BR, the panel inorganic layers 102, 103, 104, 105, 106, 107, and 109 may be removed to expose the upper surface of the substrate 101.

In the first pad area PA1, a pad electrode PAD disposed on the same layer as the first source electrode 121 (see FIG. 3) may be disposed, and a third connection electrode CNE3 disposed on the same layer as the first source electrode 121 (see FIG. 3) may be disposed on the crack sensing pattern CSP.

The first protective layer 111 may be disposed on the pad electrode PAD and the third connection electrode CNE3. The first protective layer 111 may be disposed in the bending region BR, and the first protective layer 111 may come into direct contact with the upper surface of the substrate 101 and in the bending region BR, the first protective layer 111 may come into direct contact with the side surfaces of the panel inorganic layers 102, 103, 104, 105, 106, 107, and 109.

A second connection electrode CNE2 may be disposed on the first protective layer 111, and the second connection electrode CNE2 may be disposed on the same layer as the connection electrode 145 (see FIG. 3). The second connection electrode CNE2 may electrically connect the pad electrode PAD to the third connection electrode CNE3. The second connection electrode CNE2 may be disposed on the bending region BR and may also be disposed on the first pad area PA1 and the crack sensing pattern CSP.

The data driving unit DIC may be disposed on the pad electrode PAD. The data driving unit DIC may include a bump BUMP, an anisotropic conductive film ACF may be disposed between the pad electrode PAD and the bump BUMP, and the anisotropic conductive film ACF may electrically connect the pad electrode PAD to the bump BUMP. The anisotropic conductive film ACF may include a resin SR and a plurality of conductive balls CB dispersed in the resin SR. The pad electrode PAD and the bump BUMP may be electrically connected through the conductive balls CB.

The second protective layer 112 may be disposed on the second connection electrode CNE2. The second protective layer 112 may expose the pad electrode PAD.

The first and third encapsulation layers 171 and 173 of the encapsulation part 170 may extend until before the bending region BR. For example, the first and third encapsulation layers 171 and 173 may extend until before the crack sensing pattern CSP, but the embodiments of the present specification are not limited thereto, and the first and third encapsulation layers 171 and 173 may also overlap the crack sensing pattern CSP. The first and third encapsulation layers 171 and 173 may not be disposed in the bending region BR.

The touch buffer layer 181 and the first touch insulation layer 183 may extend until before the bending region BR. For example, the touch buffer layer 181 and the first touch insulating layer 183 may extend until before the crack sensing pattern CSP, but the embodiments of the present specification are not limited thereto, and the touch buffer layer 181 and the first touch insulating layer 183 may also overlap the crack sensing pattern CSP. The touch buffer layer 181 and the first touch insulation layer 183 may not be disposed in the bending region BR.

The second touch insulating layer 184 may overlap the first dam D1 and the second dam D2. The second touch insulating layer 184 may not be disposed outside the second dam D2, but the embodiments of the present specification are not limited thereto.

A touch connection line 185′ may be electrically connected to the second connection electrode CNE2. The touch connection line 185′ may serve to provide a signal applied from the pad electrode PAD and the second connection electrode CNE2 to the first sensor electrode 185a or the second sensor electrode 185b described above in FIG. 3. The touch connection line 185′ may be located on the same layer as the second touch conductive layer (the first sensor electrode 185a of FIG. 3), but the embodiments of the present specification are not limited thereto, and the touch connection line 185′ may be located on the same layer as the first touch conductive layer (the bridge electrode 182 of FIG. 3) or formed of two first and second touch conductive layers, but the embodiments of the present specification are not limited thereto.

The filter insulating layer 114 may be disposed on the touch connection line 185′, and the filter insulating layer 114 may not be disposed in the bending region BR.

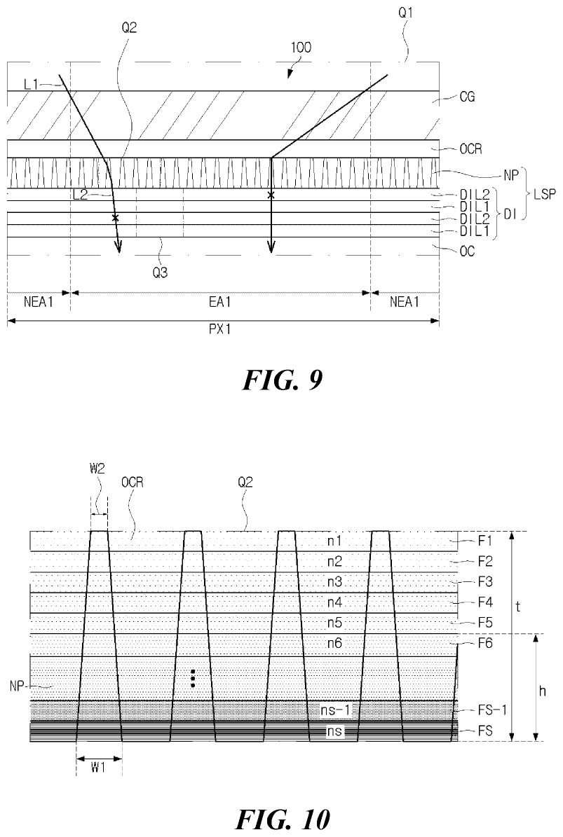

FIG. 9 is an enlarged cross-sectional view of area Q1 in FIG. 3.

In FIG. 9, only the first sub-pixel PX1 is illustrated. Referring to FIGS. 3 and 9, the optical member LSP may include a destructive interference layer DL and nano-patterns NP on the destructive interference layer DL. The nano-pattern NP may be provided as a plurality of nano-patterns. The plurality of nano-patterns NP may be disposed to be spaced apart from each other. The plurality of nano-patterns NP may be disposed both in the first light-emitting area EA1 and in the first non-light-emitting area NEA1. However, the embodiments of the present specification are not limited thereto, and the nano-patterns NP may be disposed only in the first light-emitting area EA1 and may not be disposed in the first non-light-emitting area NEA1. The upper planarization layer OCR may be disposed on the optical member LSP. The upper planarization layer OCR may come into direct contact with each nano-pattern NP. The upper planarization layer OCR may come into direct contact with an upper surface and side surfaces of the nano-pattern NP and come into direct contact with an upper surface of the destructive interference layer DL exposed by the nano-pattern NP.

The destructive interference layer DL may include a plurality of destructive interference layers DL1 and DL2. For example, the destructive interference layer DL may include a first destructive interference layer DL1 on the planarization layer OC, and a second destructive interference layer DL2 on the first destructive interference layer DL1. For example, a refractive index of the first destructive interference layer DL1 may be smaller than a refractive index of the second destructive interference layer DL2. That is, the refractive index of the second destructive interference layer DL2 may be greater than the refractive index of the first destructive interference layer DL1. For example, the first destructive interference layer DL1 may include silicon oxide, and the second destructive interference layer DL2 may include titanium oxide, but the embodiments of the present specification are not limited thereto. For example, the refractive index of the first destructive interference layer DL1 may range from about 1.4 to about 1.8, and the refractive index of the second destructive interference layer DL2 may range from about 2.4 to about 2.8, but the embodiments of the present specification are not limited thereto. For example, the first destructive interference layer DL1 and the second destructive interference layer DL2 may be provided as a plurality of destructive interference layers and alternately and repeatedly disposed upward. FIG. 9 illustrates an example in which the number of destructive interference layers DL1 and DL2 is two, but the embodiments of the present specification are not limited thereto.

The nano-pattern NP according to one embodiment may be formed integrally with the destructive interference layer DL. For example, the nano-pattern NP may be formed integrally with the second destructive interference layer DL2. The nano-pattern NP may be directly connected to the second destructive interference layer DL2 and may include the same material as the second destructive interference layer DL2. However, the nano-pattern NP may include a different material from the second destructive interference layer DL2.

The plurality of nano-patterns NP may serve to reduce a traveling angle of first light L1 (or external light) incident from the top of the cover layer CG. In addition, the plurality of nano-patterns NP may form gradient refractive indexes from the top to the bottom along with an adjacent upper planarization layer OCR, thereby suppressing surface reflection of the first light L1. When the optical member LSP is not disposed (the upper planarization layer OCR is also omitted or may be briefly provided), the first light L1 may pass through the cover layer CG, the planarization layer OC, and the color filters 191, 192, and 193 (see FIG. 3) from the top, and refractive indexes of the planarization layer OC and the color filters 191, 192, and 193 may vary according to a surrounding environment (e.g., temperature). Accordingly, to suppress the first light L1 from being reflected from interfaces between the planarization layer OC and the color filters 191, 192, and 193, even when the planarization layer OC and the color filters 191, 192, and 193 are designed to have no almost difference in refractive index, the refractive indexes of the planarization layer OC and the color filters 191, 192, and 193 varies according to the surrounding environment, and thus surface (or interface) reflection of the first light L1 inevitably occurs at the interfaces between the planarization layer OC and the color filters 191, 192, and 193. An interface reflectance may be proportional to the difference in refractive index at the interface.

However, the main purpose of one embodiment is to extinguish the first light L1 before reaching the color filters 191, 192, and 193, and to this end, by forming multiple layers “optically” having gradient refractive indexes from the top to the bottom through the nano-pattern NP and the upper planarization layer OCR, it is possible to suppress interface reflection that may occur during the process of the first light L1 reaching the destructive interference layer DL as much as possible.

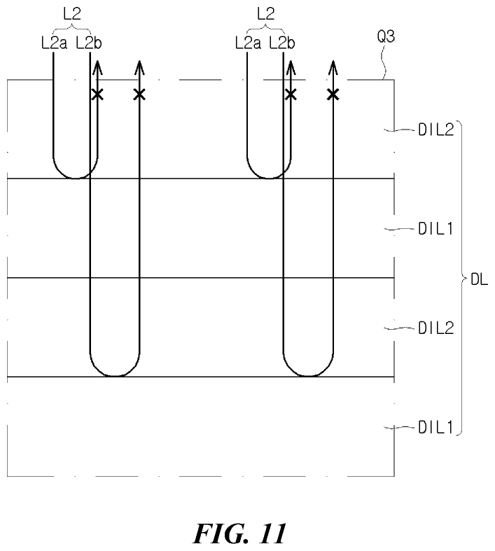

Accordingly, second light L2 that has passed through the nano-pattern NP and the upper planarization layer OCR may be extinguished by being destructively interfered by the destructive interference layer DL. Accordingly, the display panel 100 can significantly reduce the reflectance of external light. More detailed descriptions thereof will be given below in FIGS. 10 and 11.

According to the display panel according to one embodiment, since the reflection (or the surface reflection) of external light can be reduced or prevented using the color filters 191, 192, and 193 and the black matrix BM (see FIG. 3) and/or the bank 154 (see FIG. 3) (or the black bank), a polarizing unit can be deleted, and thinning can be achieved. In addition, when surface reflection occurs from the surfaces of the color filters 191, 192, and 193, it is possible to reduce or prevent the occurrence of color conversion using the optical member LSP disposed on the color filters 191, 192, and 193.

FIG. 10 is an enlarged cross-sectional view of area Q2 in FIG. 9.

Referring to FIGS. 9 and 10, the upper planarization layer OCR between the nano-patterns NP and adjacent nano-patterns NP may be formed in multiple layers F1 to FS having gradient refractive indexes. In the present specification, when the multiple layers F1 to FS have gradient refractive indexes, it do not mean that each layer is actually changed to a different material from the nano-pattern NP and the upper planarization layer OCR, but means that the first light L1 (see FIG. 9) may recognize the upper planarization layer OCR as the multiple layers F1 to FS “optically” having gradient refractive indexes.

In order for the first light L1 (see FIG. 9) to recognize the upper planarization layer OCR as the multiple layers F1 to FS “optically” having gradient refractive indexes, the following conditions need to be satisfied.

### First Condition

The first condition is that the refractive index of the nano-pattern NP needs to be greater than the refractive index of the upper planarization layer OCR. As described above, since the nano-pattern NP is formed through the same process as the second destructive interference layer DL2 having a great refractive index, the nano-pattern NP may have a greater refractive index than the upper planarization layer OCR. For example, the refractive index of the upper planarization layer OCR varies according to the surrounding environment, but may range from about 1.5 to about 1.6. For example, the refractive index of the nano-pattern NP may range from about 2.4 to about 2.8, but the embodiments of the present specification are not limited thereto.

A refractive index of each layer F1 to FS may be calculated using the following equation.

$$n = nocr + ( nnp - nocr ) \times \frac{h}{t} \times \frac{( W 1 - W 2 )}{W 1} \qquad Equation 1$$

In Equation 1, n denotes a refractive index of a specific layer F1 to FS to be calculated, nocr denotes a refractive index of the upper planarization layer OCR, nnp denotes a refractive index of the nano-pattern NP, t denotes a thickness of the nano-pattern NP, h denotes a surface height from a lower end of the nano-pattern NP to a specific layer F1 to FS to be calculated, W1 denotes a width of a lower surface of the nano-pattern NP, and W2 denotes a width of an upper surface of the nano-pattern NP.

### Second Condition

Subsequently, the second condition is that, since the refractive index of each layer F1 to FS is calculated based on densities of the nano-pattern NP and the upper planarization layer OCR in each layer F1 to FS as in Equation 1, the density of the nano-pattern NP needs to increase as it goes down (F1→F2 . . . →FS).

The increase in the density of the nano-pattern NP is related to the shape of the nano-pattern NP, and the cross-sectional shape of the nano-pattern NP may be a shape in which the width W1 of the lower surface is greater than the width W2 of the upper surface and a side surface of the nano-pattern NP is tapered. For example, the cross-sectional shape of the nano-pattern NP may be a trapezoid or a triangle, but the embodiments of the present specification are not limited thereto. The three-dimensional shape of the nano-pattern NP may be a cylinder or a cone with a tapered side surface reflecting the cross-sectional shape of the trapezoid or triangle, but the embodiments of the present specification are not limited thereto.

FIG. 11 is an enlarged cross-sectional view of area Q3 in FIG. 9.

Referring to FIG. 11, the second light L2 that has passed through the nano-pattern NP and the upper planarization layer OCR may be destructively interfered by the destructive interference layer DL. The refractive index of the second destructive interference layer DL2 may be greater than the refractive index of the first destructive interference layer DL1. The first destructive interference layer DL1 and the second destructive interference layer DL2 may be provided as a plurality of destructive interference layers and alternately and repeatedly disposed upward.

For example, some light L2a of the second light L2 may be reflected at a boundary (or an interface) between the second destructive interference layer DL2 at an uppermost end and the first destructive interference layer DL1 directly under the second destructive interference layer DL2, and other light L2b of the second light L2 may be reflected at a boundary (or an interface) between the second destructive interference layer DL2 under the first destructive interference layer DL1 and the first destructive interference layer DL1 directly under the second destructive interference layer DL2. When satisfying the destructive interference condition, some light L2a and other light L2b may cancel and may be extinguished.

According to one embodiment, thicknesses of the first destructive interference layer DL1 and the second destructive interference layer DL2 may be set to satisfy the destructive interference condition. For example, the destructive interference condition of the first destructive interference layer DL1 and the second destructive interference layer DL2 and the thicknesses for satisfying the destructive interference condition may be determined according to an incident angle (or a traveling angle) of the second light L2, and typically, may be determined in a range of a low incident angle. As described above, since the nano-patterns NP serve to reduce the traveling angle of the external light (or the first light L1) incident from the top of the cover layer CG (see FIG. 9), the second light L2 incident on the destructive interference layer DL may be highly likely destructively interfered by the destructive interference layer DL.

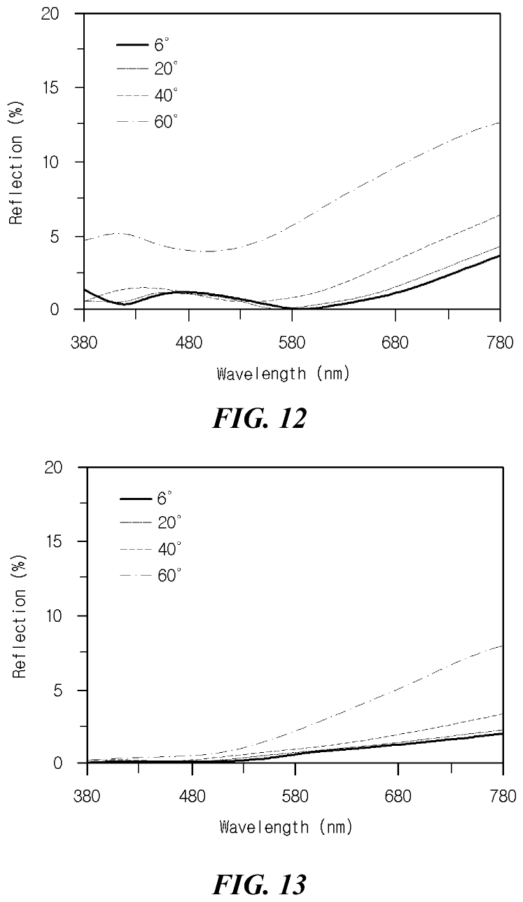

FIG. 12 is a graph illustrating a reflectance according to a wavelength when an optical member is not disposed. FIG. 13 is a graph illustrating a reflectance according to a wavelength when an optical member is disposed. FIG. 12 is a graph when the nano-patterns NP are omitted from FIG. 9, and FIG. 13 is a graph when a structure is the same as or similar to that of FIG. 9. In FIGS. 12 and 13, horizontal axes represent a wavelength (nm) of external light (e.g., a wavelength of incident external light) that is incident at 6°, 20°, 40°, and 60°, and vertical axes represent a reflectance (Reflection, %) of external light that is incident at 6°, 20°, 40°, and 60°.

As illustrated in FIGS. 12 and 13, the nano-patterns NP can reduce the reflectance of external light at various traveling angles (6°, 20°, 40°, and) 60° in all wavelength bands. As described above, the plurality of nano-patterns NP can reduce the traveling angle of external light incident from the top of the cover layer CG (see FIG. 9). Accordingly, the external light incident on the destructive interference layer DL may be highly likely destructively interfered by the destructive interference layer DL. In addition, since the nano-patterns NP form gradient refractive indexes from the top to the bottom along with the adjacent upper planarization layer OCR (see FIG. 11), it is possible to suppress the surface reflection of external light so that most of the external light incident on the nano-patterns NP and the upper planarization layer OCR may reach the destructive interference layer DL without surface reflection.

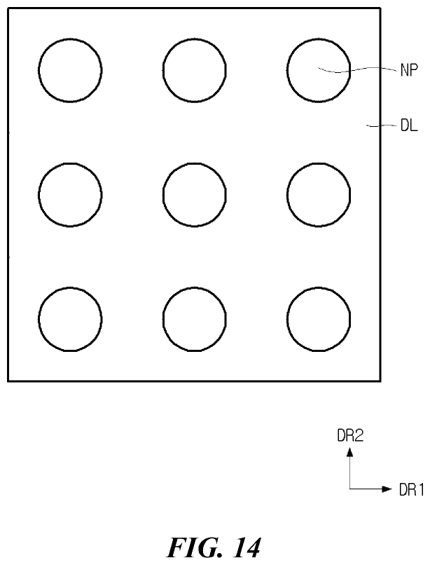

FIG. 14 is a plan view of nano-patterns according to one embodiment.

Referring to FIG. 14, the nano-patterns NP according to one embodiment may be disposed to be spaced apart from each other in a plan view. FIG. 14 illustrates the nano-patterns NP arranged in a matrix manner in the first direction DR1 and the second direction DR2, but the embodiments of the present specification are not limited thereto, and the nano-patterns NP may be arranged in various manners as long as they may satisfy Equation 1 described above in FIG. 11.

For example, the flat surface shape of the nano-pattern NP may be circular, but the embodiments of the present specification are not limited thereto, and the flat surface shape of the nano-pattern NP may be oval, rectangular, square, or other polygonal shapes.

Hereinafter, a display device according to other embodiments will be described. In the following embodiments, the detailed description of the reference numerals or components described in FIGS. 1 to 14 will be omitted or may be briefly provided, or the overlapping descriptions thereof will be omitted or may be briefly provided.

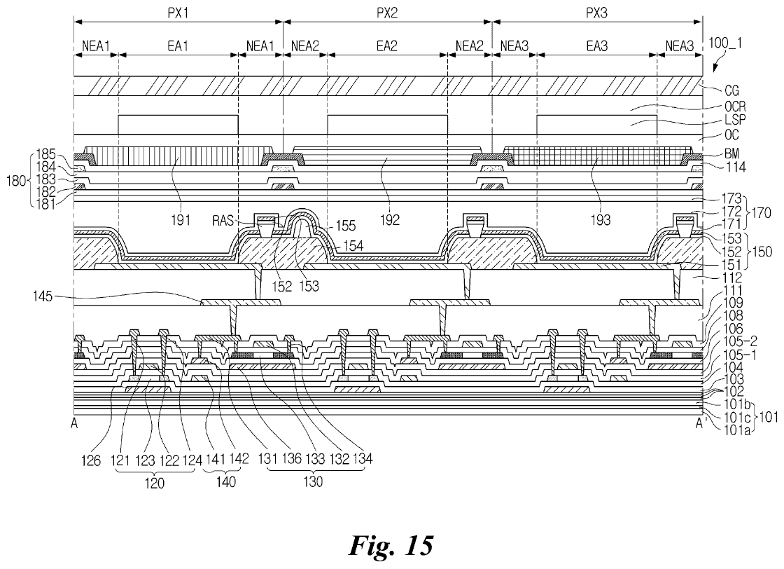

FIG. 15 is a cross-sectional view of a display device according to another embodiment.

Referring to FIG. 15, a display panel 100_1 of the display device according to the present embodiment differs from the display panel 100 according to FIG. 3 in that the optical member LSP may be disposed only in the light-emitting areas EA1, EA2, and EA3 and may not be disposed in the non-light-emitting areas NEA1, NEA2, and NEA3. The upper surface of the planarization layer OC exposed by the optical member LSP may come into direct contact with the upper planarization layer OCR.

According to the present embodiment, as described above, the optical member LSP serves to improve the surface reflection of external light, and the bank 154 capable of improving the surface reflection of external light is disposed in the non-light-emitting areas NEA1, NEA2, and NEA3. Accordingly, by arranging the optical member LSP only in the light-emitting areas EA1, EA2, and EA3, there is an advantage of cost reduction.

Since the remaining parts have been described above in FIG. 3, the detailed descriptions thereof will be omitted or may be briefly provided.

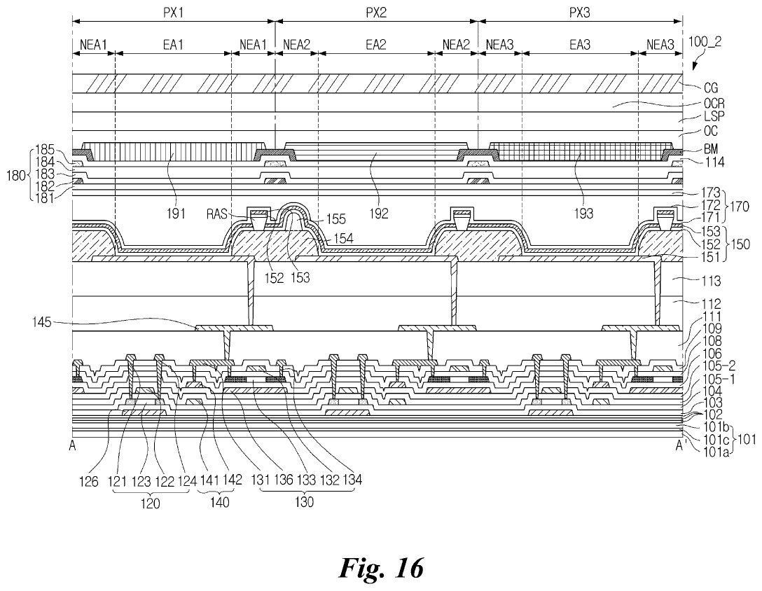

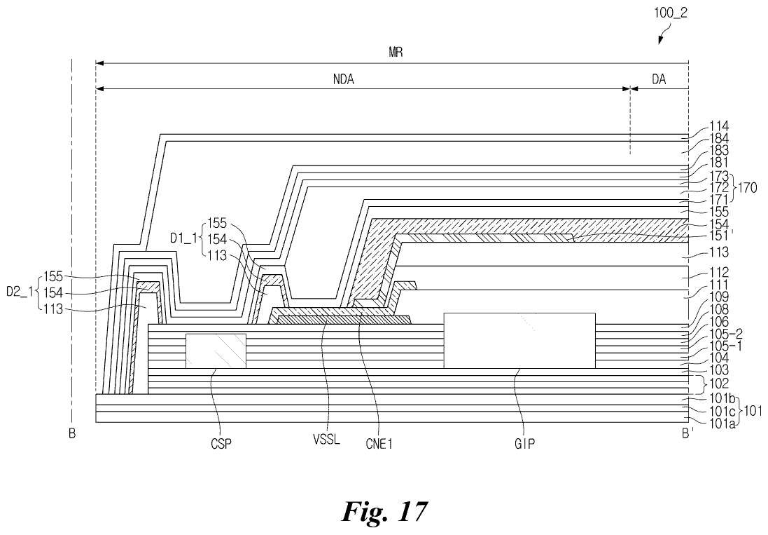

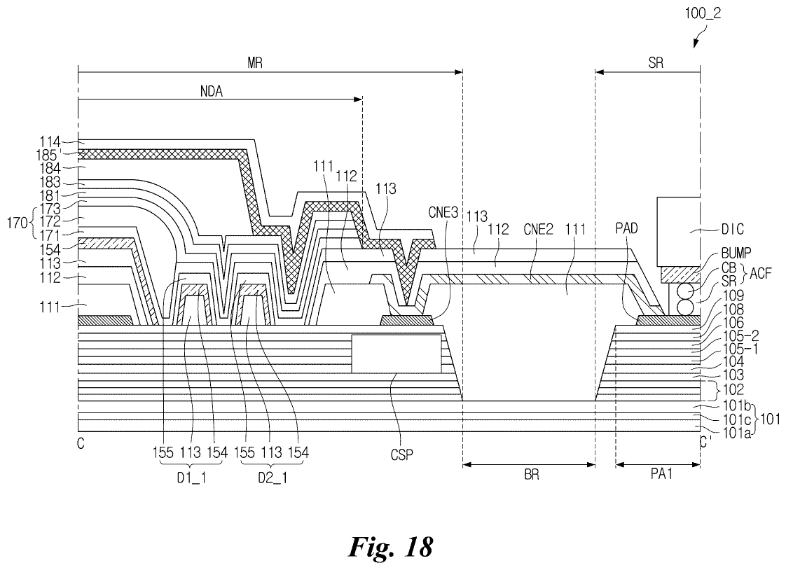

FIG. 16 is a cross-sectional view of the display device according to still another embodiment. FIG. 17 is a cross-sectional view of the display device according to still another embodiment. FIG. 18 is a cross-sectional view of the display device according to still another embodiment.

Referring to FIGS. 16 to 18, a display panel 100_2 of the display device according to the present embodiment differs from the display panel 100 according to FIGS. 3, 7, and 8 in that it may further include a third protective layer 113 on the second protective layer 112.

More specifically, the display panel 100_2 according to the present embodiment may further include the third protective layer 113 between the second protective layer 112 and the first electrode 151. A material of the third protective layer 113 may include at least one of materials exemplified as the material of the second protective layer 112, but the embodiments of the present specification are not limited thereto.

As illustrated in FIGS. 17 and 18, each of a first dam D1_1 and a second dam D2_1 may include the third protective layer 113 as a first layer and may not include the second protective layer 112, but the embodiments of the present specification are not limited thereto.

Since the remaining parts have been described above in FIGS. 3, 7, and 8, the detailed descriptions thereof will be omitted below.

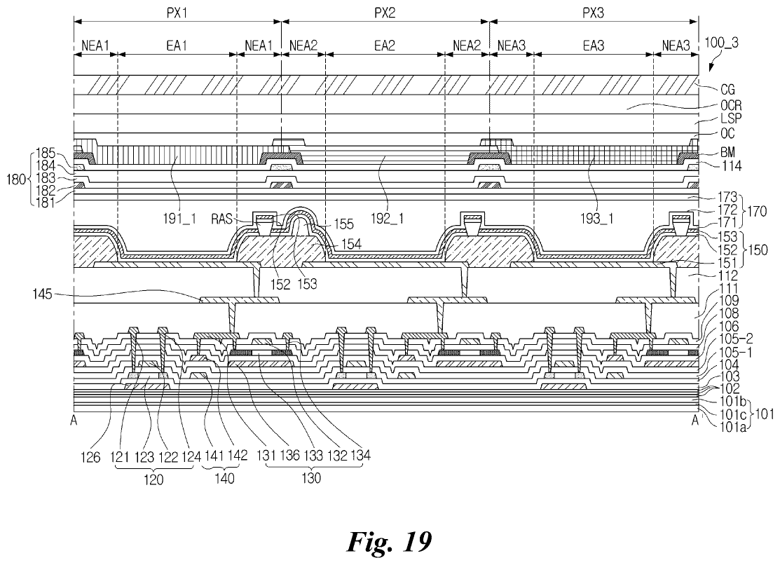

FIG. 19 is a cross-sectional view of a display device according to yet another embodiment.

Referring to FIG. 19, color filters 191_1, 192_1, and 193_1 of a display panel 100_3 of the display device according to the present embodiment differ from the display panel 100 according to FIG. 3 in that they may overlap each other in the non-light-emitting areas NEA1, NEA2, and NEA3.

FIG. 19 illustrates that a second color filter 192_1 is located at the top, a first color filter 191_1 is located under the second color filter 192_1, and lastly, a third color filter 193_1 is located at the bottom in each non-light-emitting area NEA1, NEA2, or NEA3, but the stacking order of the color filter 191_1, 192_1, and 193_1 in the non-light-emitting areas NEA1, NEA2, and NEA3 may vary according to a process order.

Since the remaining parts have been described above in FIG. 3, the detailed descriptions thereof will be omitted or may be briefly provided.

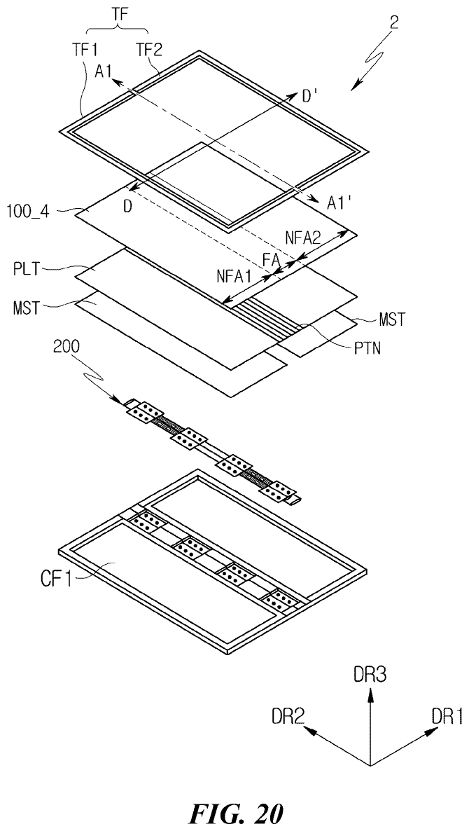

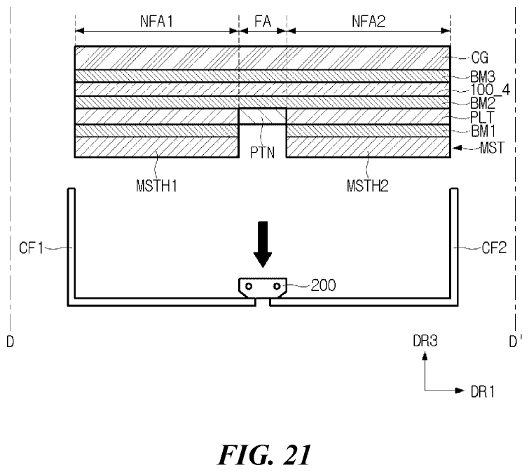

FIG. 20 is a perspective view of the display device according to yet another embodiment. FIG. 21 is a cross-sectional view along line D-D′ in FIG. 20.

Referring to FIGS. 20 and 21, a display device 2 according to the present embodiment differs from the display device 1 according to FIG. 1 in that it is a foldable display device.

In the present specification, a folding axis A1 along which the display device 2 is folded may be the same as or similar to the second direction DR2.

A top frame TF is disposed at the top of the display device 2. With respect to the folding axis A1, the top frame TF includes a first top frame TF1 disposed at one side and a second top frame TF2 disposed at the other side. The top frame TF may be disposed to cover an edge of the display panel 100_4. The top frame TF may protect the display panel 100_4 from an external impact. The top frame TF may form a bezel of the display device 2.

The cover layer CG may be disposed under the top frame TF. The cover layer CG may be disposed above the display panel 100_4.

The cover layer CG may be disposed above the display panel 100_4 to protect members disposed under the cover layer CG from the outside.

A panel assembly is disposed under the cover layer CG. The panel assembly includes the display panel 100_4 and a plate PLT. The display panel 100_4 may be substantially the same as one of the above display panels 100, 100_1, 100_2, and 100_3.

The plate PLT may be disposed under the display panel 100_4 and may include various plates for supporting the display panel 100_4. For example, one or more plates may include a back plate for supporting the display panel 100_4, a top plate disposed under the back plate and formed of a stainless steel (SUS) material, a bottom plate disposed under the top plate, having a pattern formed on a folding portion, and formed of a SUS material, a heat-dissipation sheet that performs a heat-dissipation function, a middle plate for covering a non-planarized flat surface caused by various components of a hinge assembly, etc.

A slit pattern PTN may be formed in the plate PLT. The slit pattern PTN may be formed at a location corresponding to a folding area FA of the display panel 100_4. The slit pattern PTN may be a slit-shaped etched portion formed in the plate PLT. For example, the plate PLT may be formed of a metal, such as a SUS material, but the strong nature of the metal may cause limitations in folding or unfolding the plate PLT. The slit pattern PTN may supplement the flexibility of the plate PLT.

A middle plate MST is disposed under the panel assembly. The middle plate MST supports components disposed upward. In addition, a hinge assembly 200 and a cover frame CF are disposed downward from the middle plate MST, and their upper surfaces may be uneven. The middle plate MST may flatten a non-planarized lower surface. The middle plate MST may be formed of a material, such as plastic, polyimide, or metal, to increase the rigidity of the display device 2. For example, the middle plate MST may include aluminum or SUS, but is not limited thereto.

The middle plate MST may include a first middle plate portion MSTH1 disposed in a first unfolding area NFA1, and a second middle plate portion MSTH2 disposed in a second unfolding area NFA2.

The hinge assembly 200 is disposed under the panel assembly. The hinge assembly 200 is disposed under the folding area FA. The hinge assembly 200 may have a shape extending along the folding axis A1. The hinge assembly 200 may perform a folding motion in which one side and the other side rotate about the folding axis A1.

The cover frame CF is disposed under the hinge assembly 200. An accommodation groove in which a part of the hinge assembly 200 may be seated may be formed in an upper surface of the cover frame CF. With respect to the folding axis A1, the cover frame CF includes a first cover frame CF1 disposed at one side and a second cover frame CF2 disposed at the other side. The cover frame CF may be a housing for defining the side and rear surfaces of the display device 2. The cover frame CF may protect the display device 2 from an external impact. The cover frame CF may be coupled to the hinge assembly 200. Folding and unfolding of the display device 2 may be implemented according to the rotation of the cover frames CF1 and CF2.

Coupling members BM1, BM2, and BM3 for coupling the adjacent members MST, PLT, PNL, and CG may be further disposed between the adjacent members. In each of the unfolding areas NFA1 and NFA2, a first coupling member BM1 may couple the middle plate portions MSTH1 and MSTH2 to the plate PLT disposed above the middle plate portions MSTH1 and MSTH2, a second coupling member BM2 may couple the plates PLT and slit pattern PTN to the display panel 100_4 disposed above the plates PLT and slit pattern PTN, and a third coupling member BM3 may couple the display panel 100_4 to the cover layer CG.

The plate PLT and the middle plate MST that are coupled may be seated on the cover frames CF1 and CF2. The display device 2 may perform folding and unfolding operations by the hinge assembly 200 disposed on the cover frames CF1 and CF2.

Since the display panel 100_4 has been described above, the detailed descriptions thereof will be omitted below.

A display device according to various embodiments of the present specification may be described as follows.

According to embodiments of the present specification, there is provided a display device including a substrate including a display area including a plurality of sub-pixels, and a non-display area surrounding the display area, a first electrode disposed in each of the sub-pixels on the substrate, a bank disposed on the first electrode, located at a boundary between adjacent sub-pixels, and overlapping a periphery of an upper surface of the first electrode, an organic layer on the first electrode and the bank, a second electrode on the organic layer, a color filter on the second electrode, and an optical member on the color filter, in which the bank includes a black-based material, and the optical member includes a destructive interference layer, and nano-patterns spaced apart from each other on the destructive interference layer.

In the display device according to the embodiments of the present specification, the destructive interference layer and the nano-pattern may be directly connected.

In the display device according to the embodiments of the present specification, the destructive interference layer may include a first destructive interference layer, and a second destructive interference layer on the first destructive interference layer, and a refractive index of the second destructive interference layer may be greater than a refractive index of the first destructive interference layer.

In the display device according to the embodiments of the present specification, the second destructive interference layer may include the same material as the nano-pattern.

In the display device according to the embodiments of the present specification, the first destructive interference layer and the second destructive interference layer may be disposed alternately and repeatedly.

In the display device according to the embodiments of the present specification, a width of a lower surface of the nano-pattern may be greater than a width of an upper surface of the nano-pattern.

The display device according to the embodiments of the present specification may further include an upper planarization layer on the nano-pattern, in which the upper planarization layer may come into direct contact with an upper surface and side surfaces of the nano-pattern.

In the display device according to the embodiments of the present specification, the upper planarization layer may fill between adjacent nano-patterns.

In the display device according to the embodiments of the present specification, a refractive index of the nano-pattern may be greater than a refractive index of the upper planarization layer.

In the display device according to the embodiments of the present specification, the plurality of sub-pixels may include a first sub-pixel, a second sub-pixel, and a third sub-pixel, and the organic layer may be disposed across the first sub-pixel, the second sub-pixel, and the third sub-pixel.

In the display device according to the embodiments of the present specification, the organic layer may include a first light-emitting layer on the first sub-pixel, a second light-emitting layer on the second sub-pixel, and a third light-emitting layer on the third sub-pixel.

In the display device according to the embodiments of the present specification, in the each sub-pixel, each of the first light-emitting layer, the second light-emitting layer, and the third light-emitting layer may be stacked in two or more layers.

The display device according to the embodiments of the present specification may further include a black matrix located between adjacent sub-pixels between the second electrode and the color filter, in which a width of the black matrix may be smaller than a width of the bank.

In the display device according to the embodiments of the present specification, an end portion of the black matrix may be closer to the boundary between the sub-pixels than an end portion of the bank.

The display device according to the embodiments of the present specification may further include a touch part between the second electrode and the color filter, in which the touch part may include a bridge electrode, and a sensor electrode on the bridge electrode, and the black matrix may overlap the bridge electrode and the sensor electrode.

The display device according to the embodiments of the present specification may further include a first transistor between the substrate and the first electrode, and a second transistor between the first transistor and the first electrode, in which a semiconductor layer of the first transistor may include polysilicon, and a semiconductor layer of the second transistor may include oxide.

According to embodiments of the present specification, there is provided a display device including a substrate including a display area including a plurality of sub-pixels, and a non-display area around the display area, a light-emitting unit disposed in each of the sub-pixels on the substrate, an optical member including a destructive interference layer on the light-emitting unit, and nano-patterns spaced apart from each other on the destructive interference layer, and an upper planarization layer disposed on the optical member and filling between adjacent nano-patterns, in which the nano-patterns change an optical path of incident external light, and the destructive interference layer destructively interferes with the external light of which the optical path has been changed.

In the display device according to the embodiments of the present specification, the destructive interference layer and the nano-pattern may be directly connected.

In the display device according to the embodiments of the present specification, the destructive interference layer may include a first destructive interference layer, and a second destructive interference layer on the first destructive interference layer, a refractive index of the second destructive interference layer may be greater than a refractive index of the first destructive interference layer, and the second destructive interference layer may include the same material as the nano-pattern.

In the display device according to the embodiments of the present specification, a width of a lower surface of the nano-pattern may be greater than a width of an upper surface of the nano-pattern, and a refractive index of the nano-pattern may be greater than a refractive index of the upper planarization layer.

According to the embodiments of the present specification, by omitting the polarizing unit, the display device can have improved flexibility and can be applied to a foldable product in which a display area is folded.

According to the embodiments of the present specification, it is possible to improve external light reflection by arranging the color filter and the bank including the black-based material.

According to the embodiments of the present specification, since external light reflection can be reduce or prevented using the color filter, the black matrix, and/or the black bank, it is possible to delete the polarizing unit and implement thinning. In addition, when surface reflect occurs from the surface of the color filter, it is possible to reduce or prevent the occurrence of color conversion caused by the surface reflection using the optical member disposed on the color filter according to the embodiments of the present specification.

According to the embodiments of the present specification, it is possible to improve the reflectance of external light by arranging the optical member.

According to the embodiments of the present specification, since the optical member includes nano-patterns, it is possible to reduce or minimize the reflectance of external light and reduce the traveling angle of the external light.

According to the embodiments of the present specification, since the optical member includes the destructive interference layer under the nano-patterns, it is possible to reduce or minimize the reflectance of external light.

According to the embodiments of the present specification, the surface reflection of external light can be improved to provide low-reflection display device, thereby achieving low power.

However, effects obtainable from the present specification are not limited to the above-described effects, and other effects that are not mentioned will be able to be clearly understood by those skilled in the art to which the present specification pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical idea or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1: display device
100, 100_1, 100_2, 100_3, 100_4: display panel
D1, D2: dam

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area including a plurality of sub-pixels, and a non-display area adjacent to the display area;
a first electrode disposed in each of the sub-pixels on the substrate;
a bank on the first electrode and overlapping a periphery of an upper surface of the first electrode;
an organic layer on the first electrode and the bank;
a second electrode on the organic layer;
a color filter on the second electrode; and
an optical member on the color filter,
wherein the bank includes a black-based material, and
wherein the optical member includes a destructive interference layer, and nano-patterns spaced apart from each other on the destructive interference layer.

2. The display device of claim 1, wherein the destructive interference layer and the nano-pattern are directly connected.

3. The display device of claim 1, wherein the destructive interference layer includes a first destructive interference layer, and a second destructive interference layer on the first destructive interference layer, and a refractive index of the second destructive interference layer is greater than a refractive index of the first destructive interference layer.

4. The display device of claim 3, wherein the second destructive interference layer includes a same material as the nano-pattern.

5. The display device of claim 3, wherein the first destructive interference layer and the second destructive interference layer are disposed alternately and repeatedly.

6. The display device of claim 1, wherein a width of a lower surface of the nano-pattern is greater than a width of an upper surface of the nano-pattern.

7. The display device of claim 6, further comprising an upper planarization layer on the nano-pattern, wherein the upper planarization layer comes into direct contact with an upper surface and side surfaces of the nano-pattern.

8. The display device of claim 7, wherein the upper planarization layer is between adjacent nano-patterns.

9. The display device of claim 8, wherein a refractive index of the nano-pattern is greater than a refractive index of the upper planarization layer.

10. The display device of claim 1, wherein the plurality of sub-pixels include a first sub-pixel, a second sub-pixel, and a third sub-pixel, and the organic layer is disposed across the first sub-pixel to the third sub-pixel.

11. The display device of claim 10, wherein the organic layer includes a first light-emitting layer on the first sub-pixel, a second light-emitting layer on the second sub-pixel, and a third light-emitting layer on the third sub-pixel.

12. The display device of claim 11, wherein, in each sub-pixel, each of the first light-emitting layer, the second light-emitting layer, and the third light-emitting layer is stacked in two or more layers.

13. The display device of claim 1, further comprising a black matrix located at a boundary between adjacent sub-pixels between the second electrode and the color filter, wherein a width of the black matrix is smaller than a width of the bank.

14. The display device of claim 13, wherein an end portion of the black matrix is closer to the boundary between the adjacent sub-pixels than an end portion of the bank.

15. The display device of claim 13, further comprising a touch part between the second electrode and the color filter, wherein the touch part includes a bridge electrode, and a sensor electrode on the bridge electrode, and the black matrix overlaps the bridge electrode and the sensor electrode.

16. The display device of claim 1, further comprising:
a first transistor between the substrate and the first electrode; and
a second transistor between the first transistor and the first electrode,
wherein a semiconductor layer of the first transistor includes polysilicon, and a semiconductor layer of the second transistor includes oxide.

17. The display device of claim 1, wherein the bank is located at a boundary between adjacent sub-pixels.

18. A display device comprising:
a substrate including a display area including a plurality of sub-pixels, and a non-display area adjacent to the display area;
a light-emitting part disposed in each of the sub-pixels on the substrate;
an optical member including a destructive interference layer on the light-emitting part, and nano-patterns spaced apart from each other on the destructive interference layer; and
an upper planarization layer on the optical member, the upper planarization layer being located between adjacent nano-patterns.

19. The display device of claim 18, wherein the nano-patterns change an optical path of external light, and
wherein the destructive interference layer destructively interferes with the external light of which the optical path has been changed.

20. The display device of claim 19, wherein the destructive interference layer and the nano-pattern are directly connected.
